(19) United States
(12) Patent Application Publication
(10) Pub. No.: US 2025/0255017 A1
(43) Pub. Date: Aug. 7, 2025

(54) RADIATION DETECTION DEVICE, RADIATION IMAGING SYSTEM, RADIATION IMAGING METHOD, AND RECORDING MEDIUM

(71) Applicant: CANON KABUSHIKI KAISHA, Tokyo (JP)

(72) Inventors: KAZUTAKA OSAWA, Kanagawa (JP); TAKANORI WATANABE, Kanagawa (JP)

(21) Appl. No.: 18/989,302

(22) Filed: Dec. 20, 2024

(30) Foreign Application Priority Data
Feb. 7, 2024 (JP) 2024-016815

(51) Int. Cl. H10F 39/18; H04N 23/80; H04N 25/772; H04N 25/78

(52) U.S. Cl. CPC H10F 39/1892; H04N 23/80; H04N 25/772; H04N 25/78

(57) ABSTRACT

A radiation detection device includes a pixel array, a control unit configured to control an operation of the pixel array, a reading unit configured to read a pixel signal corresponding to the charges existing in the floating diffusion unit from each of the pixels, and a signal processing unit configured to process the read pixel signal. The control unit simultaneously transfers the charges from photoelectric conversion unit to charge holding unit in a plurality of pixels arranged in the pixel array for each frame. In a case where the pixel signals read from a certain pixel of the pixel array in two consecutive frames exceed a predetermined value, the signal processing unit corrects the pixel signal read from the certain pixel for temporally earlier one of the two consecutive frames to a smaller correction value.

### BACKGROUND

### Technical Field

The present disclosure relates to a radiation detection device and the like.

### Description of the Related Art

There has been known a radiation detector that obtains a radiation image by receiving radiation with a semiconductor element such as a CMOS image sensor without using a scintillator (wavelength converter).

JP 2023-160729 A proposes a method of obtaining a background component at a timing when an imaging target is imaged in a radiation detector that captures a radiation image with a CMOS image sensor. This is a method in which a background component included in a plurality of pixels in a certain frame is obtained using values of pixel signals read in the frame.

Furthermore, in the field of CMOS image sensors, there has been known a sensor capable of realizing a so-called global electronic shutter operation in which a shutter operation is simultaneously performed for all pixels in order to prevent image distortion occurring when a moving object is imaged.

JP 2019-9155 A discloses an imaging device capable of performing a global electronic shutter operation, the imaging device including a plurality of pixels each including a photoelectric conversion unit, a charge holding unit that holds charges transferred from the photoelectric conversion unit, and a floating diffusion unit to which the charges are transferred from the charge holding unit.

When radiation images are captured in consecutive frames using a conventional imaging device capable of performing a global electronic shutter operation, radiation that should not exist in the captured frames may appear in the radiation images.

### SUMMARY

According to the present disclosure, it is possible to provide a radiation detection device capable of performing a global electronic shutter operation and capable of suppressing appearance of radiation that should not exist in captured frames in radiation images even if the radiation images are captured in consecutive frames.

According to a first aspect of the present disclosure, a radiation detection device includes a pixel array in which a plurality of pixels are arranged, a control unit configured to control an operation of the pixel array, a reading unit configured to read a pixel signal corresponding to the charges existing in the floating diffusion unit from each of the pixels, and a signal processing unit configured to process the read pixel signal. Each of the pixels includes a photoelectric conversion unit configured to generate charges upon irradiation with radiation, a photoelectric conversion unit configured to generate charges upon irradiation with radiation, and a floating diffusion unit to which the charges are transferred from the charge holding unit. The control unit simultaneously transfers the charges from the photoelectric conversion unit to the charge holding unit in the plurality of pixels arranged in the pixel array for each frame. In a case where the pixel signals read from a certain pixel of the pixel array in two consecutive frames exceed a predetermined value, the signal processing unit corrects the pixel signal read from the certain pixel for temporally earlier one of the two consecutive frames to a smaller correction value.

According to a second aspect of the present disclosure, a radiation detection device includes a pixel array in which a plurality of pixels are arranged, a control unit configured to control an operation of the pixel array, a reading unit configured to read a pixel signal corresponding to the charges existing in the floating diffusion unit from each of the pixels, and a signal processing unit configured to process the read pixel signal. Each of the pixels includes a photoelectric conversion unit configured to generate charges upon irradiation with radiation, a photoelectric conversion unit configured to generate charges upon irradiation with radiation, and a floating diffusion unit to which the charges are transferred from the charge holding unit. The control unit simultaneously transfers the charges from the photoelectric conversion unit to the charge holding unit in the plurality of pixels arranged in the pixel array for each frame. In a case where a region where, for each of two consecutive frames, adjacent pixels whose pixel signals read have values larger than a dark-time signal value is detected, the dark-time signal value being a value of a pixel signal read from the pixel array in a case where no radiation is irradiated over the plurality of consecutive frames, the signal processing unit selects one pixel that maintains the pixel signal from among the pixels in the region, and corrects the values of the pixel signals read for pixels other than the selected one pixel in the region to the dark-time signal value. And in a case where the pixel signals do not have the dark-time signal value for a same pixel in both of the two frames after the correction, the signal processing unit replaces the pixel signal of the same pixel with the dark-time signal value in temporally earlier one of the two frames.

According to a third aspect of the present disclosure, a radiation imaging method uses a radiation detection device including, a pixel array in which a plurality of pixels are arranged, a control unit configured to control an operation of the pixel array, a reading unit configured to read a pixel signal corresponding to the charges existing in the floating diffusion unit from each of the pixels, and a signal processing unit configured to process the read pixel signal. Each of the pixels includes a photoelectric conversion unit configured to generate charges upon irradiation with radiation, a photoelectric conversion unit configured to generate charges upon irradiation with radiation, and a floating diffusion unit to which the charges are transferred from the charge holding unit. The radiation imaging method includes simultaneously transferring, by the control unit, the charges from the photoelectric conversion unit to the charge holding unit in the plurality of pixels arranged in the pixel array for each frame, and correcting, by the signal processing unit, the pixel signal read from a certain pixel for temporally earlier one of two consecutive frames to a smaller correction value in a case where the pixel signals read from the certain pixel of the pixel array in the two consecutive frames exceed a predetermined value.

Further features of the present invention will become apparent from the following description of exemplary embodiments with reference to the attached drawings.

### BRIEF DESCRIPTION OF THE DRAWINGS

FIG. 1A is a block diagram illustrating a schematic configuration of a radiation detector according to a first embodiment.

FIG. 1B is a schematic circuit diagram illustrating an example of a configuration of a pixel.

FIG. 2 is a plan view of the pixel.

FIG. 3A is a schematic cross-sectional view of the pixel taken along line A-A′ in FIG. 2.

FIG. 3B is a schematic cross-sectional view of a pixel having a memory section with a different configuration.

FIG. 4A is a schematic cross-sectional view of the pixel taken along line B-B′ in FIG. 2.

FIG. 4B is a schematic cross-sectional view of a pixel having a different element isolation structure.

FIG. 5 is a schematic diagram for explaining a timing at which an imaging element is driven.

FIG. 6A is an example of a drive pulse for a read operation performed row by row in each frame.

FIG. 6B is an example of a drive pulse for a global reset operation performed simultaneously for all pixels in each frame.

FIG. 7 is a flowchart for explaining a signal processing method according to the first embodiment.

FIG. 8 is a schematic diagram for exemplifying a trajectory in which radiation incident on a certain pixel has traveled in a semiconductor layer to an adjacent pixel.

FIG. 9 is a flowchart for explaining a signal processing method according to a second embodiment.

FIG. 10 is a flowchart for explaining a signal processing method according to a third embodiment.

FIG. 11 is a flowchart for explaining a signal processing method according to a fourth embodiment.

FIG. 12 is a flowchart for explaining a signal processing method according to a fifth embodiment.

FIG. 13 is a diagram for explaining a radiation imaging system incorporating a radiation detector.

FIG. 14A is a schematic diagram illustrating a radiation imaging system including a radiation detector.

FIG. 14B is a schematic view illustrating a configuration of a transmission electron microscope (TEM) including a radiation detector.

### DESCRIPTION OF THE EMBODIMENTS

A radiation detection device and the like according to embodiments of the present invention will be described with reference to the drawings. Note that the embodiments to be described below are exemplary, and for example, detailed configurations can be appropriately modified, when implemented, by those skilled in the art without departing from the gist of the present invention.

In the drawings referred to in the following description of embodiments, elements denoted by the same reference numerals have the same functions unless otherwise specified. In the drawings, in a case where a plurality of identical elements is arranged, the reference numerals and explanations thereof may be omitted.

In addition, since the drawings may be schematically represented for convenience of illustration and description, shapes, sizes, arrangements, and the like of elements depicted in the drawings may not exactly coincide with those of actual objects.

In the following description, the term “radiation” is a concept including electromagnetic radiation (X-rays, gamma rays, etc.), particle radiation (electron beams, proton beams, neutron beams, alpha rays, etc.), and non-ionizing radiation (radio waves, microwaves, infrared rays, visible rays, etc.). The term “radiation imaging system” refers to a general system that acquires an image of an imaging target as electronic data using radiation. The imaging target is, for example, an object to be inspected in a non-destructive inspection system, or is, for example, a patient in a medical imaging system. The term “radiation detector” is a component of the radiation imaging system, and refers to an image sensor unit that converts a radiation image into an electrical signal and acquires an image as electronic data. The “image” is an image that is continuously captured and read for two or more frames by the radiation detector.

When the arrangement of pixels is described with reference to the drawings, the term “row” refers to an arrangement in the horizontal direction, and the term “column” refers to an arrangement in the vertical direction. A diagram of a radiation detector seen through from a direction (Z direction) perpendicular to a main surface of a semiconductor layer constituting the radiation detector may be referred to as a plan view.

In the following description, an analog signal output from each pixel of a radiation detector may be referred to as a pixel signal. In addition, a signal obtained by quantizing a pixel signal into two values may be referred to as a binary pixel signal or a binarized signal. In addition, a signal obtained by quantizing a pixel signal to three or more values may be referred to as a multi-value pixel signal. In addition, an image for one frame constituted by a binary pixel signal may be referred to as a binarized image.

### First Embodiment

### Configuration of Radiation Detection Device

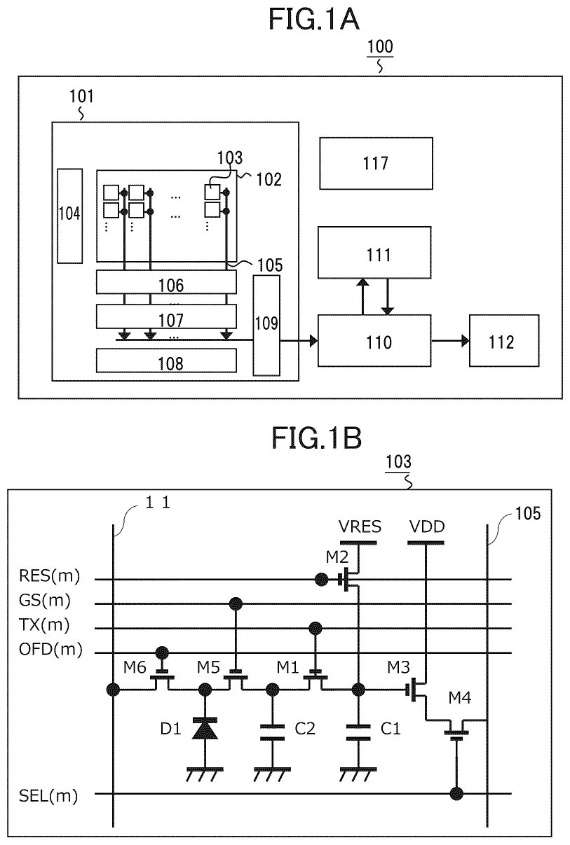

FIG. 1A is a block diagram illustrating a schematic configuration of a radiation detector 100 which is a radiation detection device according to a first embodiment. The radiation detector 100 includes an imaging element 101, an output signal processing unit 110, a memory unit 111, an external interface unit 112, and a control unit 117. Each of the functional elements illustrated is functionally conceptual, and does not need to be physically configured as illustrated. For example, the specific form in which the functional blocks are distributed or integrated is not limited to the illustrated example, and all or some of the functional blocks can be functionally or physically distributed or integrated in any unit according to the usage situation or the like.

The imaging element 101 includes a pixel array 102 in which a plurality of pixels 103 are arranged in a matrix, a vertical scanning circuit 104, column signal lines 105, a column circuit 106, a column memory 107, a horizontal scanning circuit 108, and a DFE 109. Here, DFE is an abbreviation for digital front end. The vertical scanning circuit 104, the column signal lines 105, the column circuit 106, the column memory 107, and the horizontal scanning circuit 108 are an example of a read circuit that reads pixel signals from the respective pixels of the pixel array 102 for each frame. The DFE 109 is an example of a processing circuit that processes the pixel signals read by the read circuit. The imaging element 101 is a CMOS image sensor that detects radiation.

The pixel 103 constituting the pixel array 102 converts incident radiation into a charge and generates a pixel signal, and the configuration of the pixel 103 will be described below. The vertical scanning circuit 104 selects a pixel row from which a signal in the pixel array 102 is to be output, and sequentially switches and scans the selected row. The column signal lines 105 transmit pixel signals from the pixels 103 in the row selected by the vertical scanning circuit 104. The column circuit 106 processes the pixel signals input from the column signal lines 105. The processing performed by the column circuit 106 includes analog-to-digital (A/D) conversion. The column memory 107 holds digital signals (e.g., multi-value pixel signals) output from the column circuit 106. The horizontal scanning circuit 108 scans the column circuit 106 or the column memory 107 in the pixel column direction to sequentially read the digital signal for each column. The DFE 109 is an output circuit that processes the digital signal read from the column circuit 106 or the column memory 107 and outputs the processed signal to the outside of the imaging element 101.

The output signal processing unit 110 performs signal processing using the signal output from the imaging element 101. The memory unit 111 is a data holding unit (storage area) for performing signal processing in the output signal processing unit 110, and holds data to be processed and predetermined data. The memory unit 111 preferably has a storage capacity capable of holding image signals for at least two frames. The signal output from the output signal processing unit 110 can be output to the outside of the radiation detector 100 through the external interface unit 112. Furthermore, the output signal processing unit 110 can acquire a setting value and the like necessary for signal processing from the outside through the external interface unit 112.

The control unit 117 controls the operation of each unit of the radiation detector 100, and transmits and receives signals related to operation control between the radiation detector 100 and an external device when configuring a radiation imaging system to be described below.

### Configuration of Pixel

FIG. 1B is a schematic circuit diagram illustrating an example of a configuration of the pixel 103 constituting the pixel array 102 in FIG. 1A. The pixel 103 is a pixel having a so-called global shutter function. In the following description, it is assumed that charges accumulated by a detection diode D1, which is a radiation detection element, are electrons. In the present embodiment, transistors included in the pixel 103 are all N-type transistors. Meanwhile, the charges accumulated by the detection diode D1 may be holes, and in this case, the transistors of the pixel 103 may be P-type transistors. That is, the definition of the conductivity type in the following description can be changed depending on the polarity of the charges treated as signals.

The pixel 103 included in the radiation detector according to the present embodiment includes a detection diode D1, which is a photoelectric conversion unit, a transfer transistor M5, a charge holding unit C2, a reset transistor M2, an amplification transistor M3, a selection transistor M4, a memory transfer transistor M1, a floating diffusion unit C1, and an overflow transistor M6.

The transfer transistor M5 is provided in an electrical path between the detection diode D1 and a node to which the charge holding unit C2 and the memory transfer transistor M1 are connected. A power supply voltage VRES is applied to a drain of the reset transistor M2, and a power supply voltage VDD is applied to a drain of the amplification transistor M3. The selection transistor M4 is provided in an electrical path between the amplification transistor M3 and the column signal line 105. The amplification transistor M3 is electrically connected to the column signal line 105 via the selection transistor M4. The floating diffusion unit C1 includes a floating diffusion capacitance provided in the semiconductor substrate and a parasitic capacitance of an electrical path from the memory transfer transistor M1 to the amplification transistor M3 via the floating diffusion unit. A current source (not illustrated) connected to the column signal line 105, the amplification transistor M3, and the selection transistor M4 can function as a charge-voltage conversion unit that outputs a voltage signal corresponding to charges existing in the floating diffusion unit C1 to the column signal line 105.

The memory transfer transistor M1 is provided in an electrical path between the charge holding unit C2 and the floating diffusion unit C1. The charge holding unit C2 includes a floating diffusion capacitance provided in the semiconductor substrate and a parasitic capacitance of an electrical path from the transfer transistor M5 to the memory transfer transistor M1 via the floating diffusion unit. The overflow transistor M6 is provided in an electrical path between the detection diode D1 and an overflow drain 11.

A signal RES, a signal TX, a signal SEL, a signal GS, and a signal OFD are signals supplied from the vertical scanning circuit 104 illustrated in FIG. 1A. In FIG. 1B, a pixel row to which each of the signals is supplied is added to the end of the signal. For example, (m) described at the end of each signal means that the signal is supplied to pixels of the mth row.

### Plan View and Cross-Sectional View of Pixel

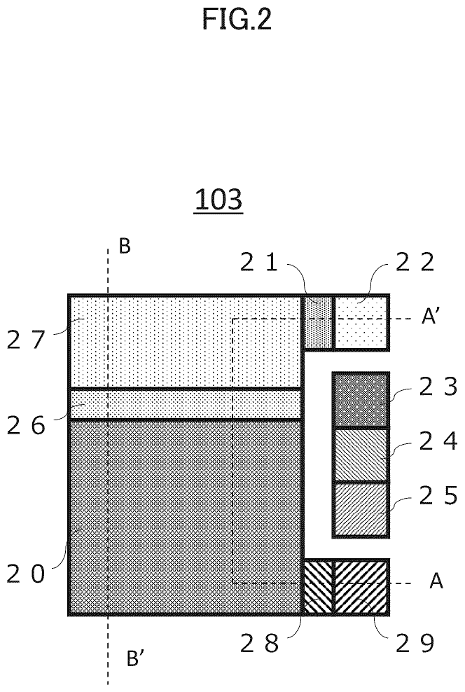

FIG. 2 is a plan view of the pixel 103 included in the radiation detector 100 according to the present embodiment. The pixel includes a detection diode section 20 including the detection diode D1, a transfer transistor section 26 including the transfer transistor M5, and a floating diffusion section 22 including the floating diffusion unit C1. The pixel further includes a reset transistor section 23 including the reset transistor M2, an amplification transistor section 24 including the amplification transistor M3, and a selection transistor section 25 including the selection transistor M4. The pixel further includes a memory transfer transistor section 21 including the memory transfer transistor M1, a memory section 27 including the charge holding unit C2, and an overflow transistor section 28 including the overflow transistor M6. The pixel further includes an overflow drain region 29 including the overflow drain 11.

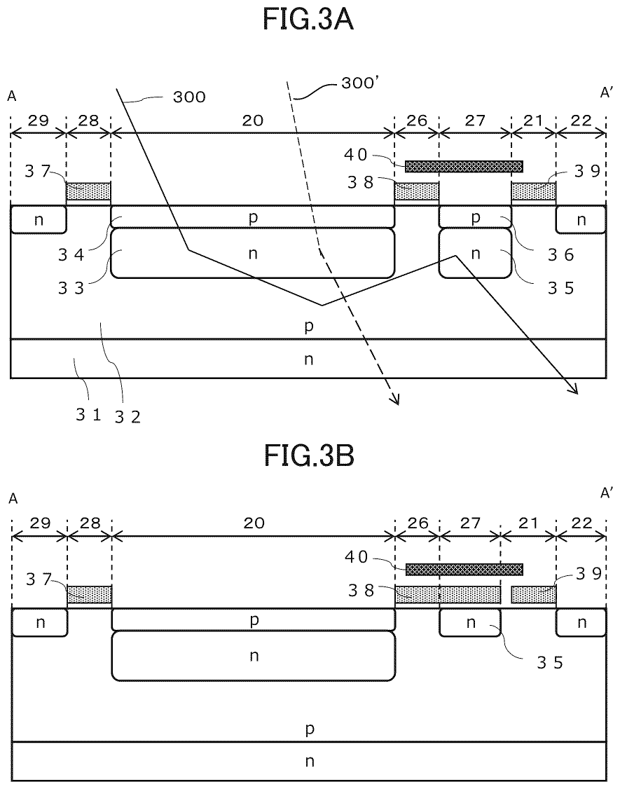

FIG. 3A is a schematic cross-sectional view of the pixel 103 taken along line A-A′ in FIG. 2. A P-type semiconductor region 32 is disposed on an N-type semiconductor substrate 31. In the detection diode section 20, an N-type semiconductor region 33 is disposed to form a PN junction with the P-type semiconductor region 32. A P-type semiconductor region 34 is disposed on a front surface side of the N-type semiconductor region 33. The P-type semiconductor region 32, the N-type semiconductor region 33, and the P-type semiconductor region 34 constitute a so-called embedded photodiode.

Similarly, in the memory section 27, an N-type semiconductor region 35 is disposed to form a PN junction with the P-type semiconductor region 32. A P-type semiconductor region 36 is disposed on a front surface side of the N-type semiconductor region 35, thereby forming a floating diffusion capacitance in the semiconductor substrate.

In FIG. 3A, a memory light-shielding film 40, which is a metal film for shielding parasitic light, is illustrated in the memory section 27, but the memory light-shielding film 40 may not be provided in some cases. Note that the configuration of the memory section 27 is not limited to the example of FIG. 3A, and the memory section 27 may be configured, for example, such that an electrode 38 is disposed above the N-type semiconductor region 35, without the P-type semiconductor region 36, as illustrated in FIG. 3B.

An electrode 37 is a gate electrode of the overflow transistor M6, and is electrically connected to the signal OFD(m) illustrated in FIG. 1B. The electrode 38 is a gate electrode of the transfer transistor M5, and is electrically connected to the signal GS(m) illustrated in FIG. 1B. An electrode 39 is a gate electrode of the memory transfer transistor M1, and is electrically connected to the signal TX(m) illustrated in FIG. 1B.

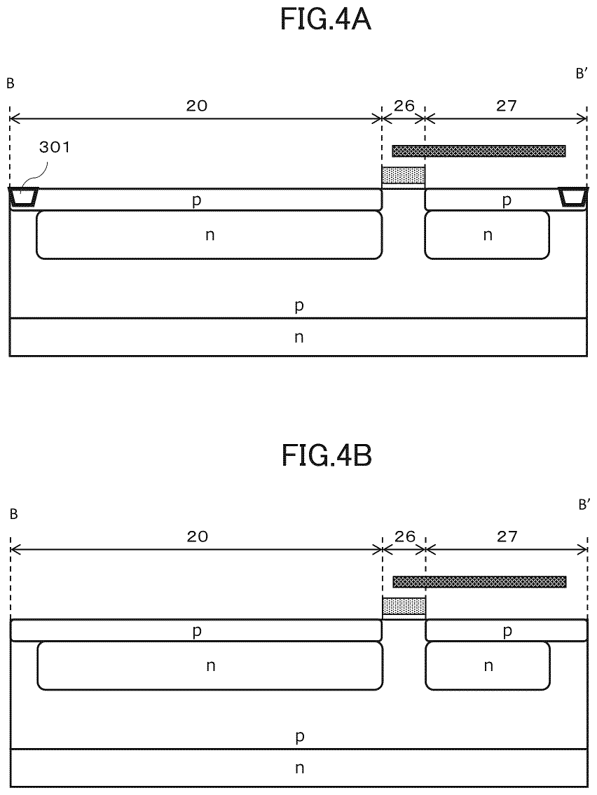

FIG. 4A is a schematic cross-sectional view of the pixel 103 taken along line B-B′ in FIG. 2. Reference numeral 301 in the drawing denotes shallow trench isolation (STI) as an element isolation structure in which an oxide film is embedded in a silicon substrate. The element isolation structure for defining an active region of each pixel is not limited to the STI, and may be configured, for example, for insulation by PN isolation as illustrated in FIG. 4B. By adopting such a configuration, it is possible to reduce the influence of the charge-up in the oxide film on the deterioration of the element, and thus, it is possible to improve the radiation resistance of the imaging device.

### Pixel Driving Timing

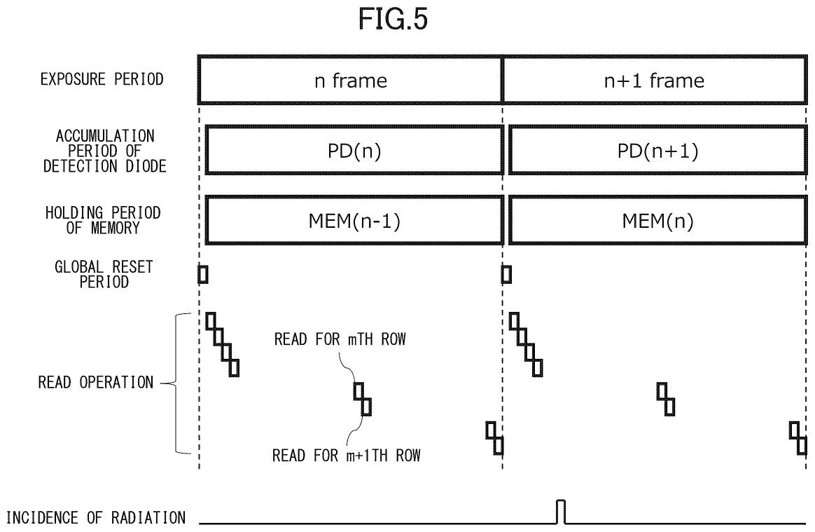

FIG. 5 is a schematic diagram for explaining a timing at which the imaging element 101 is driven. It is assumed that the time flows from the left to the right in the diagram, and an exposure period for each frame, a period during which the detection diode D1 accumulates charges, and a period during which the memory (charge holding unit C2) holds charges are shown in order from the top in the diagram.

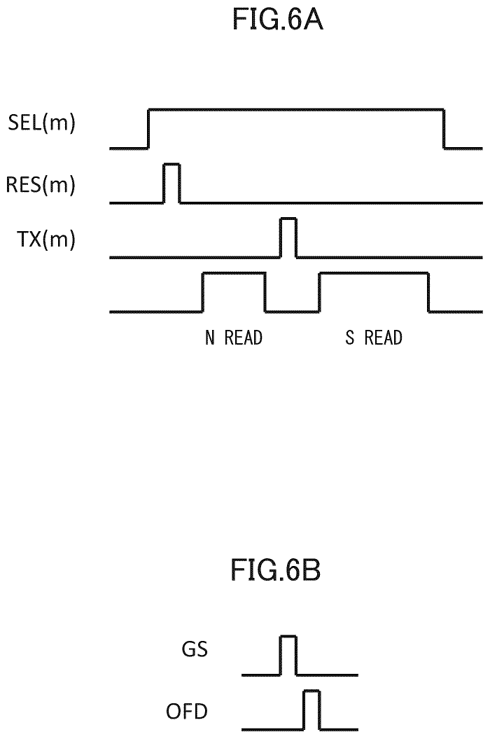

FIG. 6A illustrates an example of a drive pulse for a read operation performed in units of rows in each frame. It is assumed that the time flows from the left to the right in the diagram. During a period in which an RES pulse is at a high level, the reset transistor M2 resets the floating diffusion unit C1. During a period in which a TX pulse is at a high level, the memory transfer transistor M1 transfers charges from the charge holding unit C2 to the floating diffusion unit C1. During a period in which an SEL pulse is at a high level, the amplification transistor M3 and the selection transistor M4 output a voltage signal corresponding to the charges of the floating diffusion unit C1 to the column circuit 106 through the column signal line 105. In addition, before and after the charges are transferred by the memory transfer transistor M1, a noise signal is read (N read) and an optical signal (S read) is read for correlated double sampling (CDS).

FIG. 6B illustrates an example of a drive pulse for a global reset operation performed for all the pixels simultaneously in each frame. During a period in which a GS pulse is at a high level, the transfer transistor M5 transfers the charges detected by the detection diode D1 to the charge holding unit C2. In a period during which an OFD pulse is at a high level, the overflow transistor M6 transfers charges from the detection diode D1 to the overflow drain 11.

Returning to FIG. 5, during an “accumulation period of the detection diode” excluding a “global reset period” in the exposure period in which the radiation is irradiated, the transfer transistor M5 and the overflow transistor M6 are controlled to the OFF state. Therefore, signal charges corresponding to the irradiation of radiation are accumulated in the parasitic capacitance of the detection diode D1. During a “memory holding period”, the transfer transistor M5 and the memory transfer transistor M1 are controlled to the OFF state, and the charges held in the charge holding unit C2 are maintained. Then, as illustrated for the “read operation”, during the “accumulation period of the detection diode” common to all the pixels, the read operation is sequentially performed on each pixel in units of pixel rows.

### Behavior of Radiation Incident on Pixel

Concerning a phenomenon in which, when radiation images of consecutive frames are captured in a radiation detector capable of performing a global electronic shutter operation, radiation that should not exist in the captured frames appears in the radiation images, findings discovered by the present inventor will be described.

In FIG. 3A, trajectories of radiation 300 and radiation 300′ incident on the detection diode section 20 (detection diode D1) are exemplified. The incident radiation travels in the semiconductor layer while interacting with the substance in the pixel, sometimes changing the traveling direction, until it escapes to the outside of the semiconductor layer or until it disappears in the semiconductor layer. Like the radiation 300′, radiation may escape from the semiconductor layer without passing through an element other than the detection diode section 20, but like the radiation 300, radiation may enter a portion other than the detection diode section 20, for example, the memory section 27 (charge holding unit C2).

As exemplified in the lowermost stage of FIG. 5, in a case where radiation passes through the semiconductor layer in the trajectory indicated by the radiation 300′ at a timing during an exposure period in an (n+1) frame, signal charges are generated in the detection diode section 20, but the memory section 27 is not affected by the radiation 300′.

On the other hand, in a case where radiation passes through the semiconductor layer in the trajectory indicated by the radiation 300 at the timing during the exposure period in the (n+1) frame, the situation is different. By the action of the incident radiation 300, signal charges (in this case, electrons) are generated and accumulated in the N-type semiconductor region 33 of the detection diode section 20 as detection signals in the (n+1) frame. In a case where the radiation 300 having passed through the detection diode section 20 enters the memory section 27, charges may be generated in the N-type semiconductor region 35 of the memory section 27.

The memory section 27 holds signal charges transferred after being detected by the detection diode section 20 in the (n) frame. However, as illustrated in FIG. 3A, if the radiation irradiated in the (n+1) frame enters the memory section 27 and generates charges, the amount of signal charges of the (n) frame held in the memory section 27 varies. For example, even if no radiation is incident on the detection diode section 20 in the (n) frame, a kind of false signal may be generated as if radiation was incident in the (n) frame. The present inventor has found that when radiation is incident in the later one of the two consecutive frames, a false signal may be generated in a pixel signal of the earlier frame under the influence of the radiation, deteriorating image quality.

### Signal Processing Method

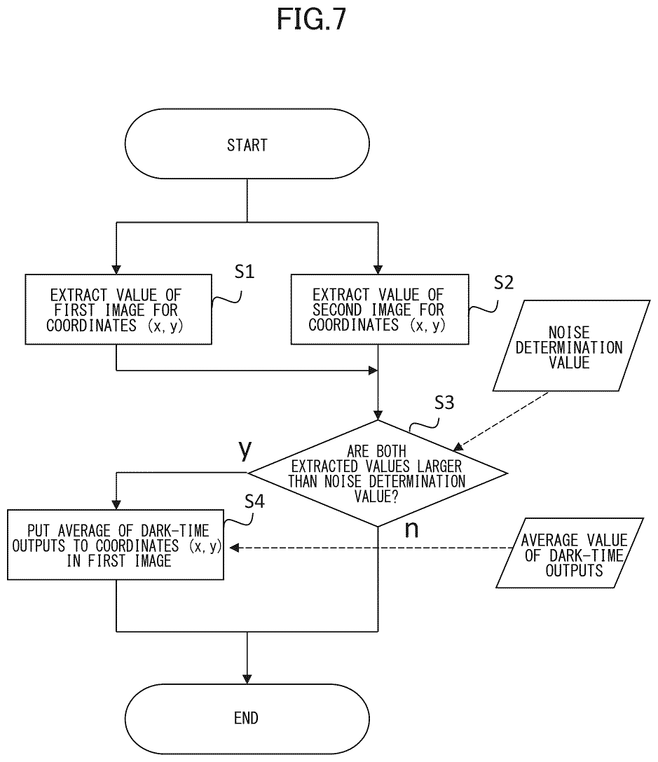

A signal processing method according to the present embodiment will be described with reference to a flowchart of FIG. 7. In FIG. 7, each pixel, which is a component of the pixel array 102, is expressed using a column address x and a row address y. Further, a read image signal of the nth frame is expressed as a “first image”, a read image signal of the n+1th frame is expressed as a “second image”, and the first image signal after being corrected by signal processing is expressed as a “first image”.

In the present embodiment, the output signal processing unit 110 illustrated in FIG. 1A performs determination processing of determining whether or not pixel signals from each pixel of the pixel array 102 exceed a predetermined value in two consecutive frames. For a pixel from which pixel signals are determined to exceed the predetermined value in the two consecutive frames in the determination processing, the output signal processing unit 110 performs correction processing of correcting a pixel signal of the temporally earlier one of the two consecutive frames to a smaller value.

The output signal processing unit 110 temporarily stores, in the memory unit 111, the pixel signals of the first image and the second image read as multi-value pixel signals via the DFE 109. Then, a pixel signal of a first image for a certain pixel is read from the memory unit 111 in step S1, and a pixel signal of a second image for the same pixel is read from the memory unit 111 in step S2. Note that the output signal processing unit 110 may process step S1 and step S2 in this order, may process step S1 and step S2 in the reverse order, or may process step S1 and step S2 simultaneously and in parallel.

Next, in step S3, the output signal processing unit 110 reads a noise determination value stored in advance from the memory unit 111. The noise determination value is a threshold for discriminating whether the read pixel signal is a noise signal in dark time when no radiation is irradiated or a signal caused by charges generated when incident radiation acts on the semiconductor layer. Note that the signal caused by the charges generated when the incident radiation acts on the semiconductor layer includes not only a signal based on signal charges generated by the incident radiation in the detection diode section 20 but also a false signal based on charges generated when the radiation enters the memory section 27 after the incidence.

The noise determination value is set as follows and stored in the memory unit 111 in advance. First, the control unit 117 reads pixel signals (dark-time signal values) from the pixel array 102 in a state where no radiation is irradiated to the pixel array 102 over two or more consecutive frames, and stores the read pixel signals in the memory unit 111. The level (dark-time signal value) of the signal read from the pixel array at this time reflects dark-time noise generated in the pixel when no radiation is irradiated, such as thermal noise and dark current.

The output signal processing unit 110 reads the dark-time pixel signals from the memory unit 111, calculates an average value, and stores the average value in the memory unit 111. The calculated average value is both a spatial average and a temporal average of dark-time noise generated in the pixel array.

The noise determination value needs to be a value capable of sufficiently distinguishing a signal level of dark-time noise and a signal level caused by irradiated radiation, and may be set based on the dark-time noise. The noise determination value is set to a value larger than the average value of dark-time noise. As a preferable example, the noise determination value can be set to three times the calculated average value of dark-time noise. In this case, while a probability that a pixel signal for a pixel to which no radiation is irradiated exceeds the noise determination value can be less than 3%, a signal level caused by irradiation of radiation exceeds the noise determination value with a high probability. The output signal processing unit 110 stores the value three times the calculated average value in the memory unit 111 as the noise determination value. Note that the value three times the average value of dark-time noise is an example of the noise determination value, and it may be required to statistically analyze signal levels of dark-time noise and signal levels of false signals and to set an appropriate noise determination value so that the discrimination ratio between the dark-time noise and the false signals can be maximized based on the statistical analysis.

The noise determination value can be set in advance by the above-described method before an object is imaged by irradiating radiation thereto, but when a long period of time elapses after the noise determination value is set, there is a possibility that the level of the dark-time noise of the imaging element changes due to irradiation of radiation or the like. Therefore, for example, immediately before a first image is captured or immediately after a second image is captured, a dark-time image may be captured in a state where no radiation is irradiated, and the noise determination value may be set based on the dark-time image. In this way, even if the characteristics of the pixels of the radiation detector change over time, the influence of the change can be reduced, thereby improving accuracy in distinguishing between dark-time noise and false signals.

In step S3 of FIG. 7, the output signal processing unit 110 reads the noise determination value and the pixel signal values of the first image and the second image for the same coordinates (pixel) acquired in the two consecutive frames from the memory unit 111. Then, the noise determination value is compared with each of the pixel signal values.

For example, when the pixel signal value of the first image is smaller than the noise determination value but the pixel signal value of the second image is larger than the noise determination value (step S3: No), the output signal processing unit 110 maintains the pixel signal values of the first image and the second image with no change for the pixel. This is because it is considered that, while no radiation was incident on the pixel in the nth frame, radiation was incident in the trajectory of the radiation 300′ illustrated in FIG. 3A in the n+1th frame, generating signal charges in the detection diode section 20, but the memory section 27 was not affected thereby.

In addition, when both the pixel signal value of the first image and the pixel signal value of the second image are smaller than the noise determination value (step S3: No), the output signal processing unit 110 maintains the pixel signal values of the first image and the second image with no change for the pixel. This is because it is considered that no radiation was incident on the pixel in either the nth frame or the n+1th frame.

On the other hand, when both the pixel signal value of the first image and the pixel signal value of the second image are larger than the noise determination value (step S3: YES), the output signal processing unit 110 proceeds to step S4. In step S4, the pixel signal value of the first image for the pixel is corrected to a smaller correction value. Specifically, the pixel signal value of the first image is changed to, for example, the average value of dark-time noise described above. This is because it is considered that, while no radiation was incident on the pixel in the nth frame, radiation was incident in the trajectory of the radiation 300 illustrated in FIG. 3A in the n+1th frame, generating signal charges in the memory section 27, and the pixel signal in the nth frame is a false signal.

The output signal processing unit 110 creates a first image′ by performing this series of processes on the pixel signals read from all the pixels 103 of the pixel array 102, and stores the first image′ in the memory unit 111. In this way, for the nth frame, the first image′, which is a high-quality radiation detection image with the reduced influence of the false signal, can be obtained.

When the imaging element 101 consecutively captures an n+2th frame subsequent to the n+1th frame, the output signal processing unit 110 executes the processing flow illustrated in FIG. 7 again with the n+1th frame as a first image and the n+2th frame as a second image. As a result, it is possible to acquire a high-quality radiation detection image with the reduced influence of the false signal for the n+1th frame as well. Furthermore, the same applies to a case where an n+3th frame, an n+4th frame, . . . are consecutively captured. According to the present embodiment, by removing a false signal generated by radiation after being incident on the semiconductor layer, noise can be reduced, and image quality can be improved.

The above-described false signal removal method is particularly effective in a system in which there is a low possibility that radiation is incident on the same pixel in consecutive frames. As a preferable embodiment, the control unit 117 controls a capture frame rate and/or a radiation irradiation rate so that the radiation irradiation rate per pixel does not exceed, for example, 0.5 during one frame period (that is, does not exceed 0.5/pix/fim).

Here, the unit [/pix/fim] of the irradiation rate is an average number of radiation particles or photons incident per frame and per pixel. In the present embodiment, the radiation irradiation rate is preferably set to 0.5/pix/frm or less. In other words, images are captured at such a low irradiation rate that a probability that radiation is incident on one pixel at a certain time is ½ or less. For example, in a case where X-rays are used, the target irradiation rate is 0.5 or less as an average number of photons incident per frame and per pixel. In a case where electron beams are used, the target irradiation rate is 0.5 or less as an average number of electrons incident per frame and per pixel. In this way, in a case where images are captured by irradiating radiation at a low irradiation rate, when pixel signal values larger than the noise determination value is read in two consecutive frames, it can be said that there is a high possibility that the pixel signal of the earlier frame indicates a false signal generated in the memory section 27. In addition, in a case where images are captured by irradiating radiation at a low irradiation rate, binarized images capable of reducing a count loss can be consecutively acquired when counting is performed as will be described below.

As described above, according to the present embodiment, in a case where radiation images are captured in consecutive frames by the global electronic shutter operation, it is possible to acquire high-quality radiation images in which false signals that should not exist in the captured frames are reduced. Although the acquired radiation image is a multi-value digital signal, the radiation detector 100 can binarize the multi-value digital signal and perform so-called counting processing. For example, an image is captured under the condition that irradiation rate is low as described above, and a binarized image in which presence or absence of incident radiation is indicated by pixel signal values 1 and 0 is created from a multi-value digital signal in which a false signal is removed. Then, by integrating a plurality of consecutive binarized images, density of incident radiation can be measured with high accuracy from gradation values of integrated pixels. For a specific determination threshold setting method and a specific counting method at the time of binarizing a multi-value digital signal, known techniques disclosed in US 2016/0309105 A1, which is a US patent publication, and WO 2019/064632 A1, which is International patent publication, can be referred to.

The processing for removing the false signal has already been performed at the stage of the multi-value digital signal. However, after the multi-value digital signal is subjected to binarization processing to express presence/absence of radiation detection in two values, frames in which there is radiation in the same pixel may be further detected and corrected.

In addition, the output signal processing unit 110 may execute so-called tracing processing on the radiation image after being binarized. In the tracing processing, it is determined whether or not pixels having a radiation-present signal level are adjacent to each other in the radiation image of the same frame after being binarized, and when there are such pixels, one pixel is determined as a pixel on which radiation is incident from among the adjacent pixels. Then, for pixels other than the determined one pixel among the adjacent pixels, the signals are corrected to a radiation-absent level.

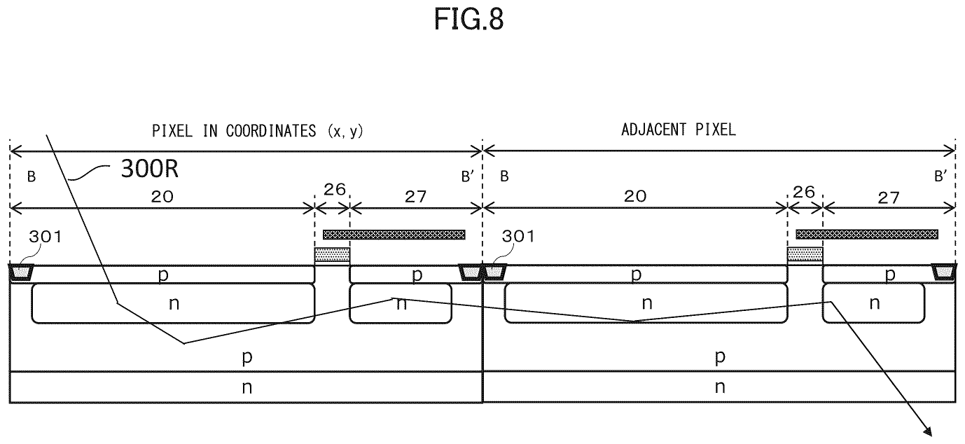

FIG. 8 is a schematic diagram for exemplifying a trajectory in which radiation incident on a certain pixel has traveled in a semiconductor layer to an adjacent pixel. FIG. 8 exemplifies cross sections of two adjacent pixels cut along line B-B′ in FIG. 2, and the two adjacent pixels may be pixels adjacent to each other in the row direction (x direction) or pixels adjacent to each other in the column direction (y direction).

As exemplified in FIG. 8, radiation 300R incident on a pixel in coordinates (x,y) may take a trajectory entering the semiconductor layer up to the inside of the adjacent pixel, and may enter the detection diode section 20 or the memory section 27 of the adjacent pixel and generate charges therein. That is, the radiation 300R incident on the pixel in coordinates (x,y) in the n+1th frame may generate false signals not only in the pixel signal of the nth frame of the pixel but also in the pixel signals of the n+1th frame and/or the nth frame of the adjacent pixel. Although a case where a false signal may be generated in only one adjacent pixel has been exemplified here for convenience of illustration, radiation may enter a wider range of pixels in the semiconductor layer depending on the conditions. Then, the incidence of one ray of radiation may cause a pixel block in which pixels having a radiation-present signal level are clustered in the read image of the n+1th frame and/or the nth frame. Note that this phenomenon is more remarkable in a high-definition radiation detection device having a small pixel pitch. In addition, this phenomenon is also remarkable in a case where the semiconductor region of the detection diode is formed thick in order to increase the detection rate.

In the tracing processing, it is determined whether or not pixels having a radiation-present signal level are adjacent to each other in the radiation image of the same frame after being binarized, and when there are such pixels, one pixel is determined as a pixel on which radiation is incident from among the adjacent pixels. Then, for pixels other than the determined one pixel among the adjacent pixels, the signal levels are corrected to a radiation-absent level. The tracing processing can be performed by a known method.

### Second Embodiment

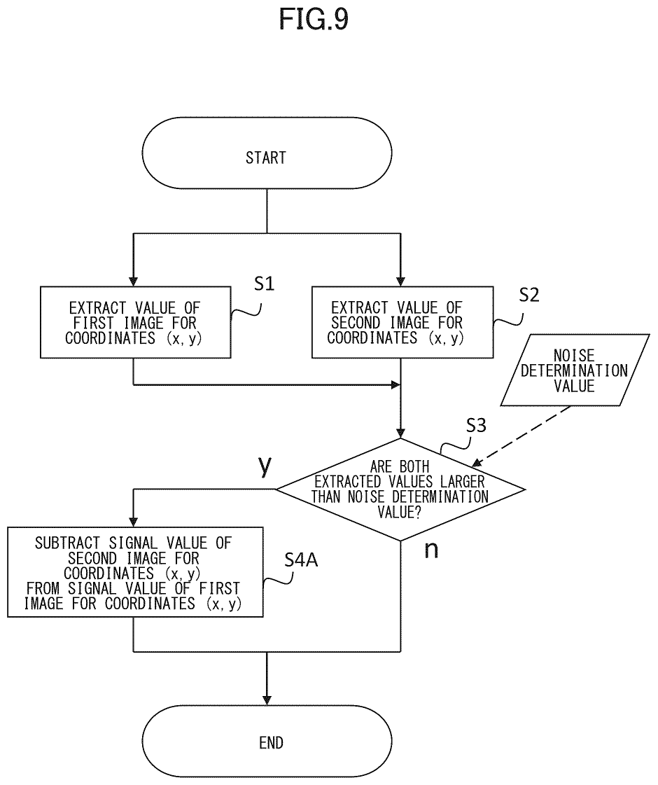

A radiation detection device according to a second embodiment will be described. The description of matters common to the first embodiment will be simplified or omitted. FIG. 9 illustrates a flowchart for explaining a signal processing method according to the second embodiment.

In the first embodiment, when both the pixel signal value of the first image and the pixel signal value of the second image are larger than the noise determination value (step S3: YES in FIG. 7), the pixel signal value of the first image is replaced with the average value of dark-time noise for the pixel in step S4.

On the other hand, in the present embodiment, as illustrated as step S4A in FIG. 9, the pixel signal value of the first image is corrected to a correction value using a method different from that of the first embodiment. In the present embodiment, when the determination result in step S3 is YES, the pixel signal value of the second image for the pixel is subtracted from the pixel signal value of the first image, and the pixel signal value of the first image is replaced with a difference value. Note that, regarding the pixel, when the pixel signal value of the second image is larger than the pixel signal value of the first image, the difference value is a negative value, but in this case, the pixel signal value of the first image is replaced with 0. When charges generated in the memory section 27 by the incidence of the radiation into the semiconductor layer are equal to or smaller than signal charges generated in the detection diode section 20, this is effective to suppress degradation in image quality based on the false signal.

According to the present embodiment, in a case where radiation images are captured in consecutive frames by the global electronic shutter operation, it is possible to acquire high-quality radiation images in which false signals that should not exist in the captured frames are reduced. Counting processing and tracing processing are similar to those in the first embodiment.

### Third Embodiment

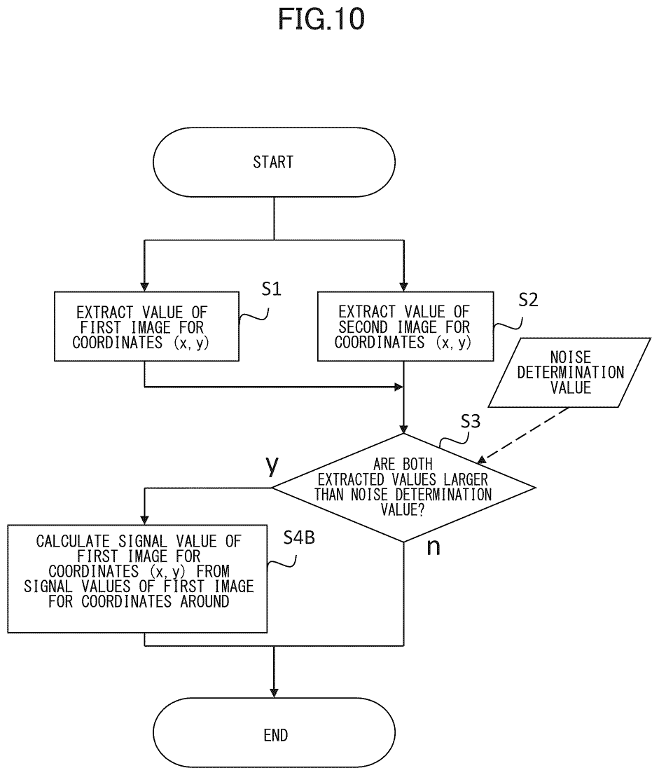

A radiation detection device according to a third embodiment will be described. The description of matters common to the first embodiment will be simplified or omitted. FIG. 10 illustrates a flowchart for explaining a signal processing method according to the third embodiment.

In the first embodiment, when both the pixel signal value of the first image and the pixel signal value of the second image are larger than the noise determination value (step S3: YES in FIG. 7), the pixel signal value of the first image is replaced with the average value of dark-time noise for the pixel in step S4.

On the other hand, in the present embodiment, as illustrated as step S4B in FIG. 10, the pixel signal value of the first image is corrected to a correction value using a method different from that of the first embodiment. In the present embodiment, when the determination result in step S3 is YES, the signal value of the first image for the pixel is calculated and replaced using signal values of first images for pixels around the pixel. For example, the signal value of the first image for the pixel may be calculated using a generally used noise smoothing method such as an average value or a median value of signal values for peripheral pixels arranged in a matrix around the target pixel. This makes it possible to perform correction while maintaining the influence of the output distribution in the screen such as shading, thereby suppressing an occurrence of an inappropriate correction mark, for example, resulting from a scratch.

According to the present embodiment, in a case where radiation images are captured in consecutive frames by the global electronic shutter operation, it is possible to acquire high-quality radiation images in which false signals that should not exist in the captured frames are reduced. Counting processing and tracing processing are similar to those in the first embodiment.

### Fourth Embodiment

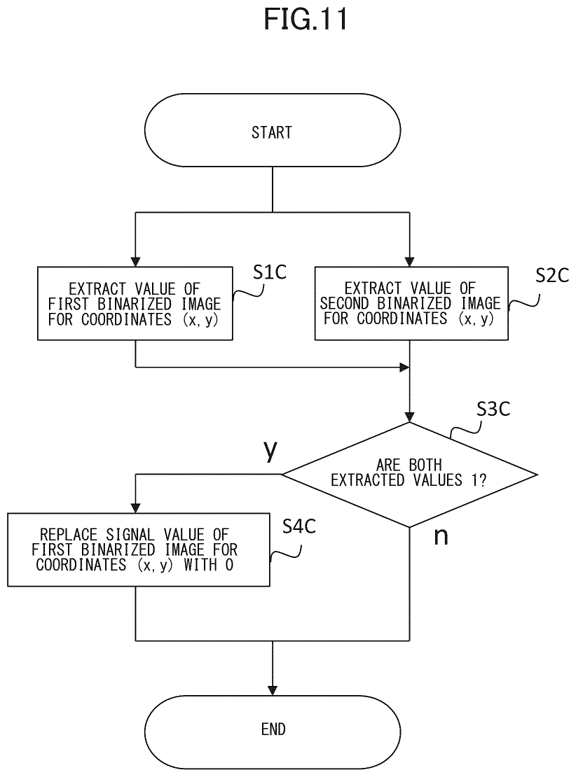

A radiation detection device according to a fourth embodiment will be described. The description of matters common to the first embodiment will be simplified or omitted. FIG. 11 illustrates a flowchart for explaining a signal processing method according to the fourth embodiment.

In the first embodiment, an A/D converter included in the column circuit 106 illustrated in FIG. 1A converts an analog voltage signal output from each pixel of the pixel array 102 into a multi-value pixel signal quantized into multiple values. Then, the output signal processing unit 110 removes a false signal component contained in the earlier frame image based on the multi-level pixel signal, and further binarizes the multi-level pixel signal after the false signal component is removed if necessary.

On the other hand, in the present embodiment, the A/D converter included in the column circuit 106 illustrated in FIG. 1A converts an analog voltage signal output from each pixel of the pixel array 102 into a binary pixel signal quantized into two values. A binarization threshold used for quantization into two values is a threshold for discriminating whether the level of the read pixel signal is a noise level in dark time when no radiation is irradiated or a signal level when signal charges are generated by incidence of radiation. Note that the signal level when signal charges are generated by incidence of radiation includes not only a signal level based on signal charges generated by the incident radiation in the detection diode section 20 but also a signal level based on the charge generated by entering the memory section 27 after the incidence of the radiation.

The binarization threshold is set as follows and stored in the memory unit 111 in advance. First, in a state where no radiation is irradiated to the imaging element 101, the control unit 117 reads multi-value pixel signals from the pixel array 102 over a plurality of consecutive frames, and stores the read multi-value pixel signals in the memory unit 111. The level of the multi-value pixel signal read from the pixel array at this time reflects dark-time noise generated in the pixel in the dark time, such as thermal noise and dark current.

The output signal processing unit 110 reads multi-value pixel signals read from all the pixels constituting the pixel array 102 over a plurality of frames from the memory unit 111, calculates an average value, and stores the average value in the memory unit 111. The calculated average value is both a spatial average and a temporal average of dark-time noise.

The binarization threshold needs to be a value capable of sufficiently distinguishing a signal level of dark-time noise and a signal level caused by irradiated radiation, and may be set to, for example, three times the calculated average value of dark-time noise. In this case, while a probability that a pixel signal for a pixel to which no radiation is irradiated exceeds the binarization threshold can be less than 3%, a signal level caused by irradiation of radiation exceeds the binarization threshold with a high probability. The output signal processing unit 110 stores, for example, three times the calculated average value as the binarization threshold (multi-value digital value), for example, in the DFE 109.

The multi-value digital value stored in the DFE 109 as the binarization threshold is converted into an analog voltage by a D/A converter, and is used as a threshold voltage when a comparator (A/D converter) included in the column circuit 106 binarizes an analog pixel signal.

In the present embodiment, the output signal processing unit 110 temporarily stores the pixel signals of the first image and the second image read as binarized images in the memory unit 111. Then, as illustrated in FIG. 11, a pixel signal of a first image for a certain pixel is read from the memory unit 111 in step S1C, and a pixel signal of a second image for the same pixel is read from the memory unit 111 in step S2C. Note that the output signal processing unit 110 may process step S1C and step S2C in this order, may process step S1C and step S2C in the reverse order, or may process step S1C and step S2C simultaneously and in parallel.

In step S3C, the output signal processing unit 110 determines whether both the pixel signal values of the first image and the second image for the same coordinates (pixel) acquired in the two consecutive frames are 1.

For example, when the pixel signal value of the first image is 0 while the pixel signal value of the second image is 1 (step S3C: No), the output signal processing unit 110 maintains the pixel signal values of the first image and the second image with no change for the pixel. This is because it is considered that, while no radiation was incident on the pixel in the nth frame, radiation was incident in the trajectory of the radiation 300′ illustrated in FIG. 3A in the n+1th frame, generating signal charges in the detection diode section 20, but the memory section 27 was not affected thereby.

In addition, when both the pixel signal value of the first image and the pixel signal value of the second image are 0 (step S3C: No), the output signal processing unit 110 maintains the pixel signal values of the first image and the second image with no change for the pixel. This is because it is considered that no radiation was incident on the pixel in either the nth frame or the n+1th frame.

On the other hand, when both the pixel signal value of the first image and the pixel signal value of the second image are 1 (step S3C: YES), the output signal processing unit 110 proceeds to step S4C and corrects the pixel signal value of the first image to 0 for the pixel. This is because it is considered that, while no radiation was incident on the pixel in the nth frame, radiation was incident in the trajectory of the radiation 300 illustrated in FIG. 3A in the n+1th frame, generating signal charges in the memory section 27, and the pixel signal in the nth frame is a false signal.

The output signal processing unit 110 creates a first image′ by performing this series of processes on the pixel signals read from all the pixels 103 of the pixel array 102, and stores the first image′ in the memory unit 111. In this way, it is possible to acquire a high-quality binary radiation detection image with the reduced influence of the false signal for the nth frame.

When the imaging element 101 consecutively captures an n+2th frame subsequent to the n+1th frame, the output signal processing unit 110 executes the processing flow illustrated in FIG. 11 again with the n+1th frame as a first image and the n+2th frame as a second image. As a result, it is possible to acquire a high-quality binary radiation detection image with the reduced influence of the false signal for the n+1th frame as well. Furthermore, the same applies to a case where an n+3th frame, an n+4th frame, . . . are consecutively captured.

According to the present embodiment, in a case where radiation images are captured in consecutive frames by the global electronic shutter operation, it is possible to acquire high-quality binarized images in which false signals that should not exist in the captured frames are reduced. The tracing processing and the counting processing described above can be executed using the obtained binarized images. Since the false signal caused by the radiation entering the semiconductor layer is removed, it is possible to prevent the incident radiation from being counted multiple times during counting. Therefore, density of incident radiation can be measured with high accuracy from the gradation values of the integrated images.

Note that, in the present embodiment, since the analog voltage signal output from the pixel is directly binarized, the memory section 27 of each pixel needs to have a capacitance capable of holding a signal charge amount larger than the binarization threshold. This makes it possible to reduce the area of the memory section 27 in plan view and reduce an increase in leakage current caused by charging up to the surface oxide film, thereby improving the radiation resistance of the imaging element.

In the above example, in step S3C, for the same pixel, it is detected whether both the pixel signal value of the first image and the pixel signal value of the second image are 1 to determine a false signal. As a method different therefrom, a region where adjacent pixels whose pixel signal values are 1 in each of consecutive frames form a cluster may be detected. When at least a part of the detected region overlaps between the consecutive frames, the entire region where the pixel signal value is 1 in the earlier frame may be determined as a false signal and corrected to 0. In a case where false signals are generated by incidence of one ray of radiation in a wide range of peripheral pixels, the false signals can be suitably removed.

### Fifth Embodiment

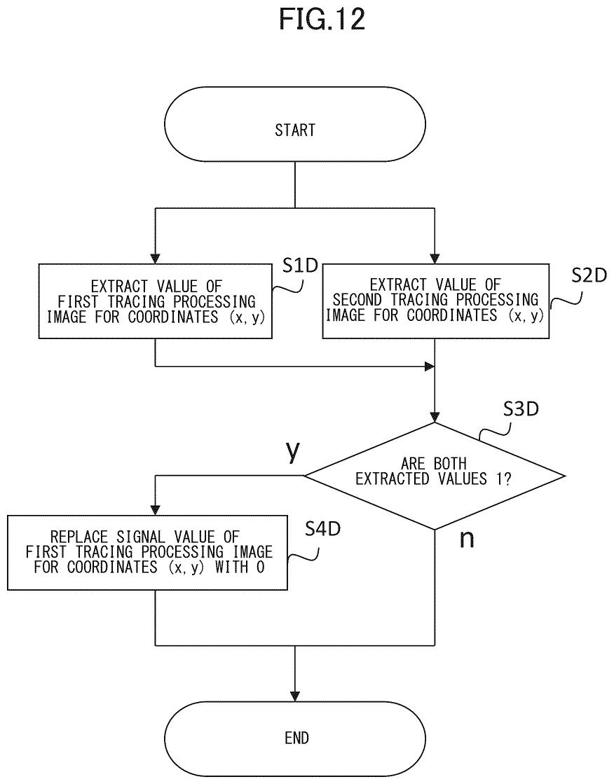

A radiation detection device according to a fifth embodiment will be described. The description of matters common to the first embodiment or the fourth embodiment will be simplified or omitted. FIG. 12 illustrates a flowchart for explaining a signal processing method according to the fifth embodiment.

In the fourth embodiment, a false signal is detected for correction based on binarized images in two consecutive frames, and tracing processing is performed using a corrected binarized image. On the other hand, in the present embodiment, the output signal processing unit 110 first performs tracing processing on each of the binarized images in the two consecutive frames.

That is, for the image of each frame, it is detected whether or not there is a pixel cluster in which pixels whose pixel signals are 1 are adjacent to each other. When a pixel cluster is detected, one pixel on which radiation is incident is determined from the pixel cluster. Then, for pixels other than the determined one pixel in the pixel cluster, their pixel signal values are corrected to 0. The binarized image in the nth frame on which tracing processing has been performed is set as a first tracing processing image, and the binarized image in the n+1th frame on which tracing processing has been performed is set as a second tracing processing image, the tracing processing images are stored in the memory unit 111.

Next, as a procedure is illustrated in FIG. 12, the output signal processing unit 110 detects and removes a false signal from the binarized image in the nth frame using the binarized image in the nth frame after tracing processing and the binarized image in the n+1th frame after tracing processing.

A pixel signal of a first tracing processing image for a certain pixel is read from the memory unit 111 in step S1D, and a pixel signal of a second tracing processing image for the same pixel is read from the memory unit 111 in step S2D. Note that the output signal processing unit 110 may process step S1D and step S2D in this order, may process step S1D and step S2D in the reverse order, or may process step S1D and step S2D simultaneously and in parallel.

In step S3D, the output signal processing unit 110 determines whether both the pixel signal values of the first tracing processing image and the second tracing processing image for the same coordinates (pixel) acquired in the two consecutive frames are 1.

For example, when the pixel signal value of the first tracing processing image is 0 while the pixel signal value of the second tracing processing image is 1 (step S3D: No), the output signal processing unit 110 maintains the pixel signal values of the first tracing processing image and the second tracing processing image for the pixel. This is because it is considered that, while no radiation was incident on the pixel in the nth frame, radiation was incident in the trajectory of the radiation 300′ illustrated in FIG. 3A in the n+1th frame, generating signal charges in the detection diode section 20, but the memory section 27 was not affected thereby.

In addition, when both the pixel signal value of the first tracing processing image and the pixel signal value of the second tracing processing image are 0 (step S3D: No), the output signal processing unit 110 maintains the pixel signal values of the first tracing processing image and the second tracing processing image for the pixel. This is because it is considered that no radiation was incident on the pixel in either the nth frame or the n+1th frame.

On the other hand, when both the pixel signal value of the first image and the pixel signal value of the second image are 1 (step S3D: YES), the output signal processing unit 110 proceeds to step S4D and corrects the pixel signal value of the first image to 0 for the pixel. This is because it is considered that, while no radiation was incident on the pixel in the nth frame, radiation was incident in the trajectory of the radiation 300R illustrated in FIG. 8 in the n+1th frame, generating signal charges in the memory section 27, and the pixel signal in the nth frame is a false signal.

The output signal processing unit 110 creates a first tracing processing image′ by performing this series of processes on the pixel signals read from all the pixels 103 of the pixel array 102, and stores the first tracing processing image′ in the memory unit 111. In this way, it is possible to acquire a high-quality binary radiation detection image with the reduced influence of the false signal for the nth frame.

When the imaging element 101 consecutively captures an n+2th frame subsequent to the n+1th frame, the output signal processing unit 110 executes the processing flow illustrated in FIG. 12 again with the n+1th frame as a first tracing processing image and the n+2th frame as a second tracing processing image. As a result, it is possible to acquire a high-quality binary radiation detection image with the reduced influence of the false signal for the n+1th frame as well. Furthermore, the same applies to a case where an n+3th frame, an n+4th frame, . . . are consecutively captured.

According to the present embodiment, by removing a false signal generated by radiation after being incident on the semiconductor layer, noise can be reduced, and image quality can be improved. The counting processing described above can be executed using the obtained binary images. Since the false signal caused by the radiation entering the semiconductor layer is removed, it is possible to prevent the incident radiation from being counted multiple times during counting. Therefore, density of incident radiation can be measured with high accuracy from the gradation values of the integrated pixels.

Note that, in the above example, when the signal of the first image after tracing processing and the signal of the second image after tracing processing for the same pixel are 1, the signal of the first image is determined as false signal. However, the identification of the pixel on which radiation is incident by the tracing processing may include an error. Therefore, when the signal of the first image after tracing processing and the signal of the second image after tracing processing are 1 in pixels within a predetermined distance, the signal of the first image may be determined as false signal. The predetermined distance may be set in a range of approximately 3 pixels to 10 pixels, depending on the device structure of the radiation detector.

The present embodiment is also effective in a case where false signals are generated across a plurality of pixels, and can be suitably implemented to achieve a high definition or a high detection rate of the imaging device.

### Sixth Embodiment

A radiation imaging system according to a sixth embodiment will be described. The description of matters common to the first embodiment to the fifth embodiment will be simplified or omitted.

### Configuration of Radiation Imaging System

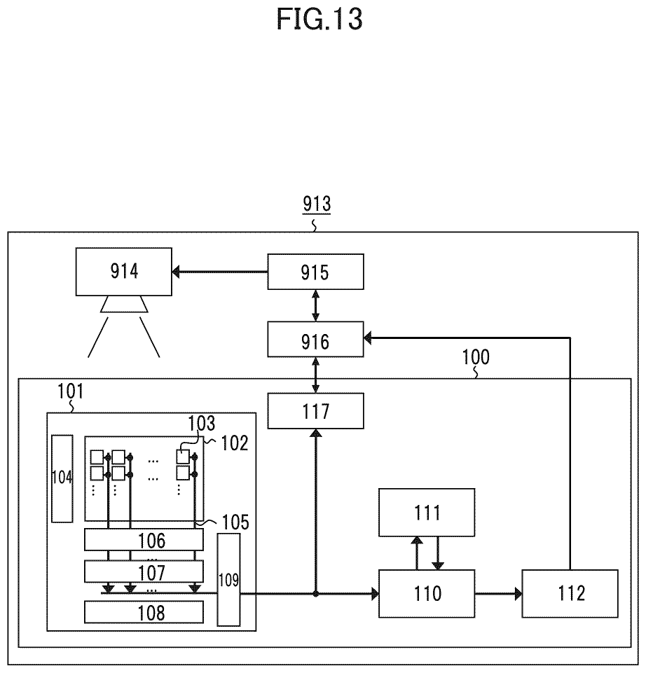

With reference to FIG. 13, a radiation imaging system 913 incorporating the radiation detector according to any one of the first to fifth embodiments described above will be described. FIG. 13 is a schematic block diagram illustrating an example of a configuration of the radiation imaging system 913 according to the present embodiment. The radiation imaging system 913 according to the present embodiment includes, for example, the radiation detector 100 illustrated in FIG. 1A, a radiation source 914, an exposure control unit 915, and a computer 916.

The radiation source 914 starts irradiating radiation in accordance with an exposure start command from the exposure control unit 915. The radiation irradiated from the radiation source 914 is transmitted through an imaging target, and is directly or indirectly incident on the imaging element 101 of the radiation detector 100. The radiation source 914 stops emitting the radiation in accordance with a stop command from the exposure control unit 915.

The radiation detector 100 includes a control unit 117 that controls a shooting frame rate and a radiation irradiation rate. The control unit 117 generates a stop signal for stopping irradiating radiation from the radiation source 914 based on a signal output from the imaging element 101. The stop signal is transmitted to the exposure control unit 915, and the exposure control unit 915 transmits a stop command to the radiation source 914 in response to the transmitted stop signal.

When the radiation is irradiated from the radiation source 914 at a high irradiation rate, the probability that two or more rays of radiation are incident on the same pixel in one frame period of the image increases. In this case, if an analog pixel signal is A/D converted to be multi-valued and then binarized using a fixed threshold at the time of acquiring a binary pixel signal, even a pixel on which two or more rays of radiation are incident is counted as 1, which may result in a count loss.

Therefore, as preferable embodiment, the control unit 117 controls a shooting frame rate and a radiation irradiation rate so that the radiation irradiation rate per pixel does not exceed, for example, 0.5 during one frame period (that is, does not exceed 0.5/pix/frm).

Here, the unit [/pix/frm] is an average number of radiation particles or photons incident per frame and per pixel. In the present embodiment, the radiation irradiation rate is set to 0.5/pix/frm or less. In other words, images are captured at such a low irradiation rate that a probability that radiation is incident on one pixel at a certain time is ½ or less. For example, in a case where X-rays are used, the target irradiation rate is 0.5 or less as an average number of photons incident per frame and per pixel. In a case where electron beams are used, the target irradiation rate is 0.5 or less as an average number of electrons incident per frame and per pixel. In this way, by capturing images at a low irradiation rate, it is possible to acquire binarized images capable of reducing a count loss when counting is performed.

Note that the control unit 117 can be constituted by, for example, a PLD (an abbreviation for programmable logic device) such as an FPGA (an abbreviation for field programmable gate array), an ASIC (an abbreviation for application specific integrated circuit), a general-purpose computer in which a program is incorporated, or a combination of all or some thereof.

The computer 916 controls, for example, the radiation detector 100 and the exposure control unit 915, and receives radiation image data from the external interface unit 112 and performs processing for displaying the radiation image data as a radiation image.

Note that the control unit 117 may be disposed separately from the radiation detector 100. For example, the computer 916 may have the function of the control unit 117. In addition, the computer 916 may function as an input unit for a user to input conditions for capturing a radiation image.

As an example, the exposure control unit 915 includes an exposure switch, and when the exposure switch is turned on by the user, an exposure command is sent from the exposure switch to the radiation source 914, and a start notification indicating the start of irradiation of radiation is sent to the computer 916. The computer 916 that has received the start notification notifies the control unit 117 of the radiation detector 100 of the start of irradiation of radiation in response to the start notification. Accordingly, the control unit 117 controls the imaging element 101 to generate a signal corresponding to the incident radiation.

The radiation detector 100 consecutively captures images of a plurality of frames while performing a global shutter operation during a period in which the radiation source 914 emits radiation. In the radiation imaging system according to the present embodiment, a false signal generated by radiation after being incident on the semiconductor layer of the imaging element can be removed, and as a result, a radiation image with high image quality can be acquired.

### Seventh Embodiment

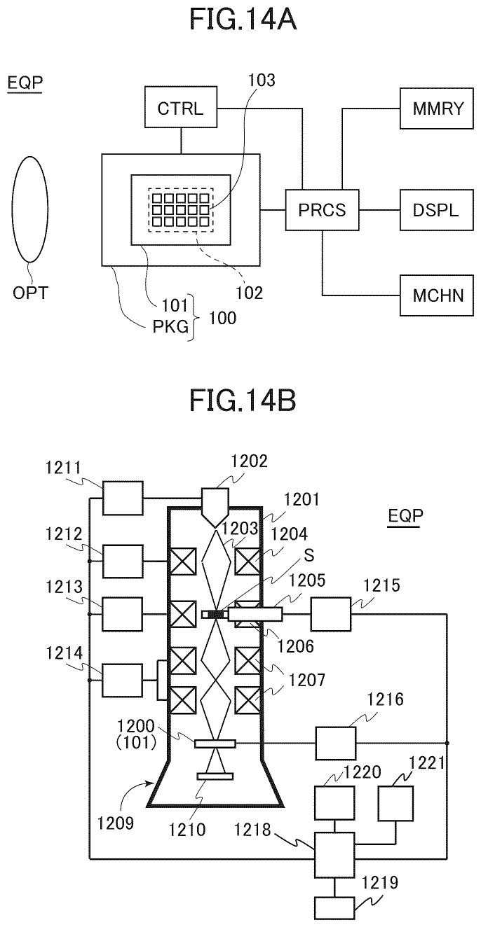

As a seventh embodiment, another example of a radiation imaging system incorporating a radiation detector will be described with reference to FIGS. 14A and 14B.

FIG. 14A illustrates equipment EQP serving as a radiation imaging system including a radiation detector 100. The radiation detector 100 includes a package PKG for mounting an imaging element 101 in addition to the imaging element 101 which is a semiconductor device.

The package PKG may include a base to which the imaging element 101 is fixed, a lid such as glass facing the imaging element 101, and a connection member such as a bonding wire or a bump that connects a terminal provided on the base and a terminal provided on the imaging element 101. The imaging element 101 includes a pixel array 102 in which pixels 103 are arranged in a matrix and a peripheral region around the pixel array 102. A peripheral circuit (for example, a vertical scanning circuit 104 and a DFE 109) can be provided in the peripheral region.

The equipment EQP may further include at least one of an optical system OPT, a control device CTRL, a processing device PRCS, a display device DSPL, a storage device MMRY, and a mechanical device MCHN. The optical system OPT forms an image of radiation on the radiation detector 100, and is, for example, a lens, a shutter, or a mirror. The optical system OPT may form an image of a particle beam such as an electron beam or a proton beam on the radiation detector 100 according to a type of radiation to be handled. The control device CTRL controls the radiation detector 100, and is, for example, an ASIC. The processing device PRCS processes a signal output from the radiation detector 100, and is a device such as a central processing unit (CPU) or an ASIC for configuring an analog front end (AFE) or a digital front end (DFE). The display device DSPL is an electroluminescence (EL) display device or a liquid crystal display device that displays information obtained by the radiation detector 100 in a form of a visible image or the like. The storage device MMRY is a magnetic device or a semiconductor device that stores information obtained by the radiation detector 100. The storage device MMRY is a volatile memory such as a static random-access memory (SRAM) or a dynamic random-access memory (DRAM), or a nonvolatile memory such as a flash memory or a hard disk drive. The mechanical device MCHN includes a movable unit such as a motor or an engine, or a propulsion unit.

The equipment EQP displays a signal output from the radiation detector 100 on the display device DSPL or transmits the signal to the outside by a communication device (not illustrated) included in the equipment EQP. Therefore, the equipment EQP preferably further includes the storage device MMRY and the processing device PRCS separately from a storage circuit and an arithmetic circuit of the radiation detector 100. The mechanical device MCHN may be controlled based on a signal output from the radiation detector 100. The equipment EQP illustrated in FIG. 14A may be medical equipment such as an endoscope or radiodiagnosis equipment, measurement equipment such as a distance measurement sensor, or analytical equipment such as an electron microscope.

FIG. 14B is a schematic diagram illustrating a configuration of a transmission electron microscope (TEM) as an example of the equipment EQP. The equipment EQP serving as an electron microscope includes an electron beam source 1202 (electron gun), an application lens 1204, a vacuum chamber 1201 (lens barrel), an objective lens 1206, a magnifying lens system 1207, and a camera 1209 serving as the radiation detector 100.

The electron beam 1203, which is an energy beam emitted from the electron beam source 1202, is focused by the application lens 1204 and is applied to a sample S serving as an analysis target held by a sample holder. A space through which the electron beam 1203 passes is formed by the vacuum chamber 1201 (lens barrel), and the space is held in vacuum. The radiation detector 100 is disposed to face the vacuum space through which the electron beam 1203 passes. The electron beam 1203 transmitted through the sample S is enlarged by the objective lens 1206 and the magnifying lens system 1207 and projected onto the radiation detector 100. An electron optical system for applying the electron beam to the sample S is referred to as an application optical system, and an electron optical system for forming an image of the electron beam transmitted through the sample S on the radiation detector 100 is referred to as an imaging optical system.

The electron beam source 1202 is controlled by an electron beam source control device 1211. The application lens 1204 is controlled by an application lens control device 1212. The objective lens 1206 is controlled by an objective lens control device 1213. The magnifying lens system 1207 is controlled by a magnifying lens system control device 1214. A control mechanism 1205 of the sample holder is controlled by a holder control device 1215 that controls a drive mechanism of the sample holder.

The electron beam 1203 transmitted through the sample S is detected by a direct detector 1200 of the camera 1209. An output signal from the direct detector 1200 is processed by a signal processing device 1216 and an image processing device 1218 serving as the processing devices PRCS to generate an image signal. The generated image signal (transmitted electron image) is displayed on an image display monitor 1220 and an analysis monitor 1221 corresponding to the display device DSPL.

The camera 1209 is provided below the equipment EQP. The camera 1209 includes the direct detector 1200 (direct electron detector). The direct detector 1200 corresponds to the imaging element 101. The direct detector 1200 is provided in the camera 1209 such that at least a part of the camera 1209 is exposed to the vacuum space formed by the vacuum chamber 1201.

Each of the electron beam source control device 1211, the application lens control device 1212, the objective lens control device 1213, the magnifying lens system control device 1214, and the holder control device 1215 is connected to the image processing device 1218. As a result, data can be exchanged with each other in order to set imaging conditions of the electron microscope. For example, an application rate of the electron beam can be set so as to be 0.5 electron/pix/frm or less. In this case, the electron beam source control device 1211 and the image processing device 1218 function as a control unit that controls a radiation application rate. Drive control of the sample holder and observation conditions of each lens can be set according to a signal from the image processing device 1218.

An operator prepares the sample S to be imaged, and sets imaging conditions by using an input device 1219 connected to the image processing device 1218. Predetermined data is input to each of the electron beam source control device 1211, the application lens control device 1212, the objective lens control device 1213, and the magnifying lens system control device 1214, and a desired acceleration voltage, magnification, and observation mode are obtained. In addition, the operator inputs conditions such as the number of consecutive visual field images, an imaging start position, and a movement speed of the sample holder to the image processing device 1218 by using the input device 1219 such as a mouse, a keyboard, or a touch panel. Alternatively, the image processing device 1218 may automatically set the conditions without depending on the operator's input.

A direct detector 1200 serving as a radiation detector consecutively captures images of a plurality of frames while performing a global shutter operation during a period in which an electron beam source 1202 emits an electron beam. In the radiation imaging system according to the present embodiment, a false signal generated by an electron beam after being incident on the semiconductor layer of the imaging element can be removed, and as a result, a radiation image with high image quality can be acquired. The radiation imaging system described above in the seventh embodiment is merely an example, and the radiation detectors described in the first to fifth embodiments may be applied to other systems.

### Other Embodiments

Note that the present invention is not limited to the above-described embodiments and examples, and many modifications can be made within the technical spirit of the present invention. For example, all or some of the different embodiments described above may be combined for implementation.

In each of the first to fifth embodiments, the example has been described in which the output signal processing unit 110 and the memory unit 111 are configured separately from the imaging element 101 in the radiation detector 100. In other words, the example has been described in which the processing of removing the false signal generated by the radiation after being incident on the semiconductor layer of the imaging element 101 is performed by a chip different from the imaging element 101. However, processing of detecting and correcting a false signal is not necessarily performed outside the imaging element 101. For example, the output signal processing unit 110 and the memory unit 111 for detecting and correcting a false signal may be mounted on the same chip (e.g., the semiconductor substrate) as the imaging element 101. Conversely, image signals of consecutive frames may be transmitted from the radiation detector 100 to an external computer via the external interface unit 112, and the computer may perform processing of detecting and correcting a false signal using the image signals.

In each of the first to fifth embodiments, the example has been described in which determination processing of determining whether or not pixel signals exceed the predetermined value in two consecutive frames is performed on digital signals obtained by A/D converting the pixel signals read from the pixel array. However, determination processing and correction processing may be performed on an analog signal by using an analog calculator capable of calculating an analog signal and an analog memory capable of holding an analog signal.

The radiation detection element included in the pixel of the radiation detection device may be a conversion element such as a detection diode formed on a semiconductor substrate such as silicon, or may be a conversion element formed of cadmium telluride or cadmium zinc telluride. The radiation detector may be a detector using a single photon avalanche diode (SPAD).

The radiation detection device to which the present invention can be applied is not limited to the exemplary embodiments, and for example, the radiation receiving portion may be either a front side illumination type or a back side illumination type. In addition, the radiation detection device to which the present invention can be applied may be a stack-type radiation detection device in which a semiconductor chip including a radiation receiving unit and a semiconductor chip including a logic unit are stacked.

A program capable of executing the signal processing method and the radiation imaging method described above is also included in the embodiments of the present invention. In addition, a computer-readable recording medium in which the program is recorded is also included in the embodiments of the present invention.

The present invention can also be realized by processing in which a program for implementing one or more functions of the embodiments is supplied to a system or a device via a network or a storage medium, and one or more processors in a computer of the system or the device read and execute the program. The present invention can also be realized by a circuit (e.g., ASIC) that implements one or more functions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-16815, filed Feb. 7, 2024, which is hereby incorporated by reference herein in its entirety.

What is claimed is:

1. A radiation detection device comprising:
a pixel array in which a plurality of pixels are arranged, each of the pixels including:
a photoelectric conversion unit configured to generate charges upon irradiation with radiation;
a photoelectric conversion unit configured to generate charges upon irradiation with radiation; and
a floating diffusion unit to which the charges are transferred from the charge holding unit;
a control unit configured to control an operation of the pixel array;
a reading unit configured to read a pixel signal corresponding to the charges existing in the floating diffusion unit from each of the pixels; and
a signal processing unit configured to process the read pixel signal,
wherein the control unit simultaneously transfers the charges from the photoelectric conversion unit to the charge holding unit in the plurality of pixels arranged in the pixel array for each frame, and
in a case where the pixel signals read from a certain pixel of the pixel array in two consecutive frames exceed a predetermined value, the signal processing unit corrects the pixel signal read from the certain pixel for temporally earlier one of the two consecutive frames to a smaller correction value.

2. The radiation detection device according to claim 1, wherein
the predetermined value is a threshold for discriminating a first pixel signal and a second pixel signal from each other,
the first pixel signal being a pixel signal read from the certain pixel in a case where the pixel array is not irradiated with radiation over two or more consecutive frames, and
the second pixel signal being a pixel signal read from the certain pixel as a pixel signal of a frame immediately before a certain frame in a case where, in the certain frame, the photoelectric conversion unit of the certain pixel is irradiated with radiation, and the radiation enters the charge holding unit of the certain pixel and charges are generated in the charge holding unit of the certain pixel.

3. The radiation detection device according to claim 1, wherein
the predetermined value is a threshold for discriminating a first pixel signal and a second pixel signal from each other,
the first pixel signal being a pixel signal read from the certain pixel in a case where the pixel array is not irradiated with radiation over two or more consecutive frames, and
the second pixel signal being a pixel signal read from the certain pixel according to charges transferred from the charge holding unit to the floating diffusion unit in a case where the photoelectric conversion unit of the certain pixel is irradiated with radiation, and the radiation enters the charge holding unit of the certain pixel and charges are generated in the charge holding unit of the certain pixel.

4. The radiation detection device according to claim 1, wherein
the predetermined value is a threshold for discriminating a first pixel signal and a second pixel signal from each other,
the first pixel signal being a pixel signal read from the certain pixel in a case where the pixel array is not irradiated with radiation over two or more consecutive frames, and
the second pixel signal being a pixel signal read from the certain pixel as a pixel signal of a frame immediately before a certain frame in a case where, in the certain frame, a pixel adjacent to the certain pixel is irradiated with radiation, and the radiation enters the charge holding unit of the certain pixel and charges are generated in the charge holding unit of the certain pixel.

5. The radiation detection device according to claim 1, wherein
the predetermined value is a value larger than an average value of pixel signals read from the plurality of pixels in a case where the pixel array is not irradiated with radiation over two or more consecutive frames.

6. The radiation detection device according to claim 1, wherein
the pixel array is driven in a state where an average number of photons or particles of radiation incident per frame and per pixel is 0.5 or less.

7. The radiation detection device according to claim 1, wherein
the reading unit includes:
a charge-voltage conversion unit configured to convert charges existing in the floating diffusion unit for each of the pixels into a voltage signal, and read the voltage signal; and
an analog-to-digital (A/D) converter configured to convert the read voltage signal into a digital signal.

8. The radiation detection device according to claim 7, wherein
the A/D converter is an A/D converter that converts the voltage signal into a digital signal of three or more values, and
the correction value is set based on a value obtained by reading a voltage signal from the pixel array in advance and converting the voltage signal into a digital signal by the A/D converter in a case where no radiation is irradiated over a plurality of consecutive frames.

9. The radiation detection device according to claim 7, wherein
the A/D converter is an A/D converter that converts the voltage signal into a digital signal of three or more values, and
the correction value is a difference value between the digital signal of the certain pixel in temporally later one of the two consecutive frames and the digital signal of the certain pixel in a temporally earlier frame.

10. The radiation detection device according to claim 7, wherein
the A/D converter is an A/D converter that converts the voltage signal into a digital signal of three or more values, and
the signal processing unit calculates the correction value using the digital signals of pixels around the certain pixel in the temporally earlier frame.

11. The radiation detection device according to claim 7, wherein
the A/D converter is an A/D converter that converts the voltage signal into a digital signal of three or more values, and
the signal processing unit binarizes the digital signal of three or more values converted into the correction value in the temporally earlier frame.

12. The radiation detection device according to claim 7, wherein
the A/D converter performs binarization processing of converting the voltage signal into a binarized signal, and
the correction value is a value of a binarized signal obtained by reading a voltage signal read from the pixel array in advance and converting the voltage signal into a digital signal by the A/D converter in a case where no radiation is irradiated over a plurality of consecutive frames.

13. The radiation detection device according to claim 11, wherein
in a case where a region where adjacent pixels whose binarized signals have values larger than a dark-time signal value in the temporally earlier frame is detected, the dark-time signal value being a value of a binarized signal read from the pixel array in a case where no radiation is irradiated over a plurality of consecutive frames,
the signal processing unit selects one pixel that maintains the binarized signal from among the pixels in the region, and corrects the values of the binarized signals for pixels other than the selected one pixel in the region to the dark-time signal value.

14. A radiation detection device comprising:
a pixel array in which a plurality of pixels are arranged, each of the pixels including:
a photoelectric conversion unit configured to generate charges upon irradiation with radiation;
a charge holding unit configured to hold the charges transferred from the photoelectric conversion unit; and
a floating diffusion unit to which the charges are transferred from the charge holding unit;
a control unit configured to control an operation of the pixel array;
a reading unit configured to read a binarized pixel signal from each of the pixels of the pixel array according to the charges existing in the floating diffusion unit; and
a signal processing unit configured to process the read binarized pixel signal,
wherein the control unit simultaneously transfers the charges from the photoelectric conversion unit to the charge holding unit in the plurality of pixels arranged in the pixel array for each frame,
in a case where a region where, for each of two consecutive frames, adjacent pixels whose pixel signals read have values larger than a dark-time signal value is detected, the dark-time signal value being a value of a pixel signal read from the pixel array in a case where no radiation is irradiated over the plurality of consecutive frames,
the signal processing unit selects one pixel that maintains the pixel signal from among the pixels in the region, and corrects the values of the pixel signals read for pixels other than the selected one pixel in the region to the dark-time signal value, and
in a case where the pixel signals do not have the dark-time signal value for a same pixel in both of the two frames after the correction, the signal processing unit replaces the pixel signal of the same pixel with the dark-time signal value in temporally earlier one of the two frames.

15. The radiation detection device according to claim 1, wherein
the signal processing unit is disposed on a chip where the pixel array is formed.

16. The radiation detection device according to claim 1, wherein
the signal processing unit is disposed outside a chip where the pixel array is formed.

17. A radiation imaging system comprising:
the radiation detection device according to claim 1; and
a radiation source configured to irradiate an object to be imaged with radiation.

18. The radiation imaging system according to claim 17, wherein
the radiation source controls a radiation irradiation rate such that an average number of photons or particles of radiation incident per frame and per pixel is 0.5 or less.

19. A radiation imaging method using a radiation detection device including:
a pixel array in which a plurality of pixels are arranged, each of the pixels including:
a photoelectric conversion unit configured to generate charges upon irradiation with radiation;
a charge holding unit configured to hold the charges transferred from the photoelectric conversion unit; and
a floating diffusion unit to which the charges are transferred from the charge holding unit;
a control unit configured to control an operation of the pixel array;
a reading unit configured to read a pixel signal corresponding to the charges existing in the floating diffusion unit from each of the pixels; and
a signal processing unit configured to process the read pixel signal,
the radiation imaging method comprising:
simultaneously transferring, by the control unit, the charges from the photoelectric conversion unit to the charge holding unit in the plurality of pixels arranged in the pixel array for each frame; and
correcting, by the signal processing unit, the pixel signal read from a certain pixel for temporally earlier one of two consecutive frames to a smaller correction value in a case where the pixel signals read from the certain pixel of the pixel array in the two consecutive frames exceed a predetermined value.

20. A computer-readable recording medium recording a program for causing a signal processing unit to execute the radiation imaging method according to claim 19.
